(19) United States
(12) Patent Application Publication
(10) Pub. No.: US 2010/0204934 A1
(43) Pub. Date: Aug. 12, 2010

(54) SEMICONDUCTOR DEVICE, POWER SUPPLY CURRENT MEASURING DEVICE AND METHOD OF MEASURING POWER SUPPLY

(75) Inventors: Tatsushi Gotou, Yokohama-shi (JP); Hajime Ikeda, Kawasaki-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/700,111

(22) Filed: Feb. 4, 2010

(30) Foreign Application Priority Data
Feb. 10, 2009 (JP) 2009-28252

(51) Int. Cl. G06F 19/00; G01R 21/06

(52) U.S. Cl. 702/60; 702/120

(57) ABSTRACT

A semiconductor device has an input/output terminal configured to input test patterns, a plurality of function blocks configured to be driven by power supply voltage supplied through separate power supply lines, an internal bus configured to send and receive at least the test patterns between the function blocks and the input/output terminal, and an input control circuit which is provided corresponding to each of the plurality of function blocks and switches whether to provide the test patterns on the internal bus to the corresponding function block based on a mode setting signal.

### CROSS REFERENCE TO RELATED APPLICATIONS

This application is based upon and claims the benefit of priority from the prior Japanese Patent Applications No. 2009-28252, filed on Feb. 10, 2009, the entire contents of which are incorporated herein by reference.

### BACKGROUND OF THE INVENTION

1. Field of the Invention

The invention relates to a semiconductor device having a plurality of function blocks, a power supply current measuring device and a method of measuring power supply.

2. Related Art

Recent semiconductor devices have multiple function blocks, each of which has a specific function in general. In order to measure consumption power of the function blocks or to inspect whether or not the function blocks work properly, it is necessary to measure power supply current of each of the function blocks.

Test patterns provided to the function block in order to measure the power supply current depend on function blocks. Therefore, in order to measure the power supply current of the function blocks, each of the function blocks have to be provided with the test patterns from an LSI (large-scale integrated circuit) tester.

However, an input terminal for inputting a signal from outside of the semiconductor device is provided for each of the function blocks. Therefore, connection between the LSI tester and the input terminal of each of the function blocks has to be switched every time the test pattern is provided to the input terminal. This results in measuring the power supply current for each of the function blocks and it may take a long time to measure the power supply current.

JP-A No. 2001-60653 (Kokai) (hereinafter, “Patent Document 1”) discloses a technique for measuring the power supply current efficiently when all the function blocks are supplied with a common power supply. However, in recent years, the function blocks are diversified and an operation voltage differs depending on function blocks. Because of this and of some other reason, each function block is often supplied with a power supply voltage different from each other by a respective power supply device. The Patent Document 1 does not at all assume the measurement of the power supply current of the semiconductor device having such function blocks for multiple power supply devices.

### SUMMARY

According to one aspect of the present invention, a semiconductor device comprising: an input/output terminal configured to input test patterns; a plurality of function blocks configured to be driven by power supply voltage supplied through separate power supply lines; an internal bus configured to send and receive at least the test patterns between the function blocks and the input/output terminal; and an input control circuit which is provided corresponding to each of the plurality of function blocks and switches whether to provide the test patterns on the internal bus to the corresponding function block based on a mode setting signal.

According to the other aspect of the present invention, a power supply current measuring device comprising: a large-scale integrated circuit (LSI) tester configured to provide test patterns and a mode setting signal; an internal bus configured to send and receive at least the test patterns between a plurality of function blocks driven by power supply voltages supplied through separate power supply lines and the LSI tester; an input control circuit which is provided corresponding to each of the plurality of function blocks and switches whether to provide the test patterns on the internal bus to the corresponding function block based on the mode setting signal; and a plurality of ampere meters configured to simultaneously measure a power supply current of the plurality of function blocks.

According to the other aspect of the present invention, a power supply current measuring method comprising: outputting a test pattern and a mode setting signal from a large-scale integrated circuit (LSI) tester; providing a plurality of function blocks driven by power supply voltages supplied through separate power supply line with the test pattern through an internal bus between the plurality of function blocks and the LSI tester; switching whether to provide the test pattern on the internal bus to the corresponding function block based on the mode setting signal by an input control circuit corresponding to each of the plurality of function blocks; and measuring a power supply current of the plurality of function blocks by a plurality of ampere meters simultaneously.

### BRIEF DESCRIPTION OF THE DRAWINGS

FIG. 1 is a block diagram showing a schematic configuration of a power supply current measuring device 101 according to an embodiment of the present invention.

FIG. 2 is a schematic diagram showing an internal configuration of the interface circuit 2a.

FIG. 3 is a flowchart showing a processing operation of the power supply current measuring device 101 and the LSI tester 8 according to the present embodiment.

### DETAILED DESCRIPTION OF THE INVENTION

Hereinafter, a semiconductor device, a power supply current measuring device and a method of measuring power supply according to embodiments of the present invention will be specifically explained with reference to accompanying drawings.

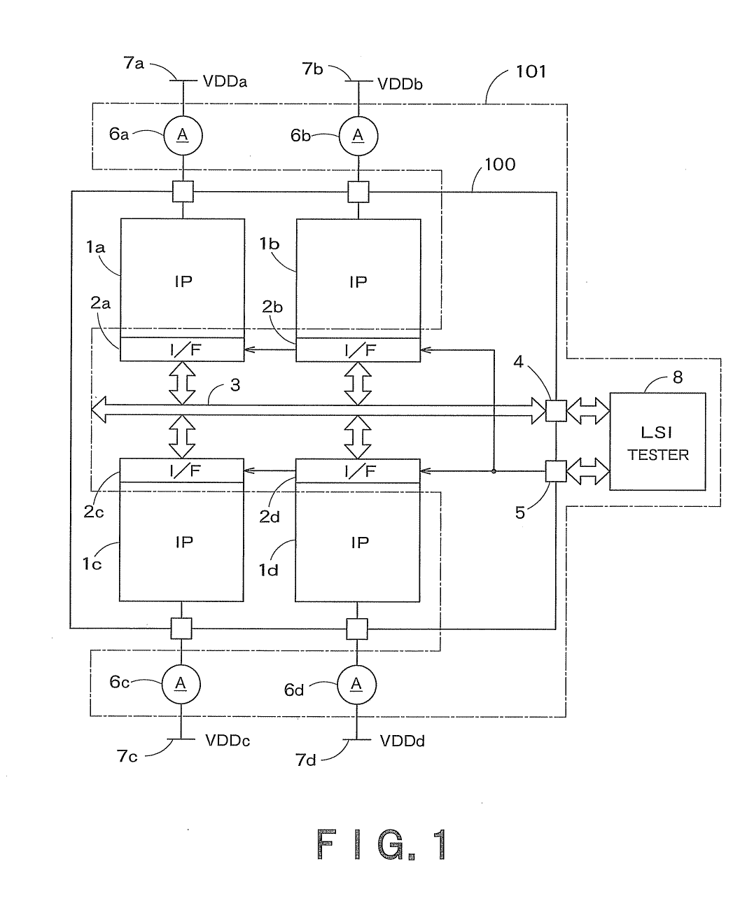

FIG. 1 is a block diagram showing a schematic configuration of a power supply current measuring device 101 according to an embodiment of the present invention. The power supply current measuring device 101 of FIG. 1 intends to measure the power supply current passing through a plurality of function blocks is to 1d in a semiconductor device 100. The power supply current measuring device 101 includes a part of components inside of the semiconductor device 100, a plurality of ampere meters 6a to 6d, and an LSI tester 8.

The semiconductor device 100 has a plurality of function blocks (IP: Intellectual Property blocks) 1a to 1d, a plurality of interface circuit (I/F) 2a to 2d, an internal bus 3, an input/output terminal 4, and a mode setting terminal 5. These components except the function blocks 1a to 1d work as a part of the power supply current measuring device 101.

Each of the function blocks 1a to 1d has various functions by itself. These functions include, for example, functions of a video decoder/encoder, a USB (Universal Serial Bus) interface. The ampere meters 6a to 6d for measuring the power supply current are connected to the function blocks 1a to 1d, respectively. Furthermore, the function blocks 1a to 1d are supplied with power supply voltages VDDa to VDDd by separate power supply devices 7a to 7d. In addition, the function blocks is to 1d are provided with a common or separate internal clock (not shown).

The interface circuits 2a to 2d are provided corresponding to the function blocks 1a to 1d, respectively. The interface circuits 2a to 2d are interfaces between the internal bus 3 and the function blocks 1a to 1d, respectively. The detail will be explained below.

The internal bus 3 is used for sending and receiving various data including test patterns between the input/output terminal 4 and the interface circuits 2a to 2d. The test patterns are generated by LSI tester 8 provided separately from the semiconductor device 100 and inputted to the input/output terminal 4. The internal bus 3 is used for transmitting the test patterns when measuring the power supply current. However, on normal operation, the internal bus 3 can be used for transmitting data between the function blocks 1a to 1d or between function blocks 1a to 1d and the input/output terminal 4. Therefore, in the present embodiment, it is unnecessary to provide the internal bus 3 used only for measuring the power supply current.

The LSI tester 8 can provide all the function blocks is to 1d with the test patterns for measuring the power supply current through the common input/output terminal 4. Furthermore, the LSI tester 8 obtains data outputted by the function blocks 1a to 1d through the input/output terminal 4. This data includes information indicative of status of each function block, such as whether each of the function blocks is under operation or under preparation for operation. The LSI tester 8 determines whether or not the function blocks 1a to 1d are in a status where the power supply current can be measured or the like based on the obtained data. In addition, the LSI tester 8 inputs a mode setting signal through the mode setting terminal 5 to the interface circuits 2a to 2d and sets the operating status of the interface circuits 2a to 2d. The mode setting signal includes information indicating that which of the interface circuits 2a to 2d is set to the operating status. That is, the mode setting signal sets the operating status of one of the interface circuits 2a to 2d.

The type and/or the number of the function blocks in the semiconductor device 100 in the present embodiment are not limited. The power supply voltages VDDa to VDDd can be the same or can be different from each other. The LSI tester 8 can be composed of multiple devices. The mode setting signal can be inputted to the interface circuits 2a to 2d via the other interface circuit as shown in FIG. 1 or can be inputted directly to each of the interface circuits 2a to 2d from the mode setting terminal 5.

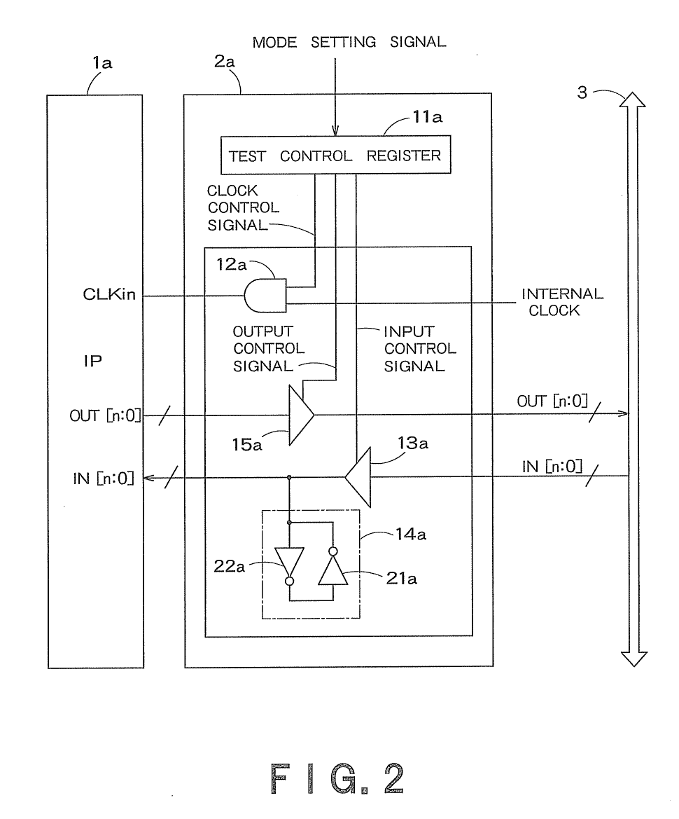

FIG. 2 is a schematic diagram showing an internal configuration of the interface circuit 2a and a periphery thereof. The interface circuit 2a is one of characteristic features of the present embodiment. Because the internal configurations of the interface, circuits 2a to 2d are the same, the internal configuration of the interface circuit 2a is representatively shown in FIG. 2. The interface circuit 2a has a test control register 11a, a clock stop circuit 12a, an input control circuit 13a, a data hold circuit 14a, and an output control circuit 15a.

The test control register 11a generates a clock control signal for controlling the clock stop circuit 12a, an input control signal for controlling the input control circuit 13a, and an output control signal for controlling the output control circuit 15a based on the mode setting signal.

The clock stop circuit 12a switches whether or not to provide a clock input terminal CLKin of the function block 1a with the internal clock based on the clock control signal. The clock stop circuit 12a is, for example, composed of an AND circuit. In this case, when the clock control signal is in Low, the clock input terminal CLKin is not provided with the internal clock.

The input control circuit 13a switches whether or not to provide a data input terminal IN[n:0] of the function block 1a with data on the internal bus 3 based on the input control signal. The output control circuit 15a switches whether or not to output data from an output terminal OUT[n:0] of the function block 1a to the internal bus 3 based on the output control signal. The input control circuit 13a and the output control circuit 15a are, for example, composed of CMOS switches, respectively.

As mentioned above, the mode setting signal includes information indicative of whether or not to provide each of the function blocks 1a to 1d with the internal clock, information indicating that which of the function blocks 1a to 1d is provided with which of the test patterns, and information indicative of whether or not to provide the internal bus 3 with the output data (signal) of the function blocks 1a to 1d. Based on the mode setting signal, the clock control signal, the input control signal, and the output control signal are generated.

The data hold circuit 14a holds data inputted from the internal bus 3 through the input control circuit 13a to provide the function block 1a with the holding data. The data hold circuit 14a is, for example, composed of two inverters 21a and 22a connected in a shape of a ring to perform a holding operation. In the data hold circuit 14a, the inverter 21a is fed back to input its output to the inverter 22a, and the inverter 22a is fed back to input its output to the inverter 21a.

The interface circuits 2b to 2d whose internal configurations are the same as that shown in FIG. 2 are provided corresponding to the function blocks 1b to 1d. By providing the interface circuits 2a to 2d, the test patterns provided by the LSI tester 8 to the internal bus 3 through the input/output terminal 4 are held by the data hold circuit 14a in the corresponding interface circuit in accordance with the mode setting signal.

Here, “data” mentioned above includes not only the test patterns for measuring the power supply current, but also address signals and various control signals or the like.

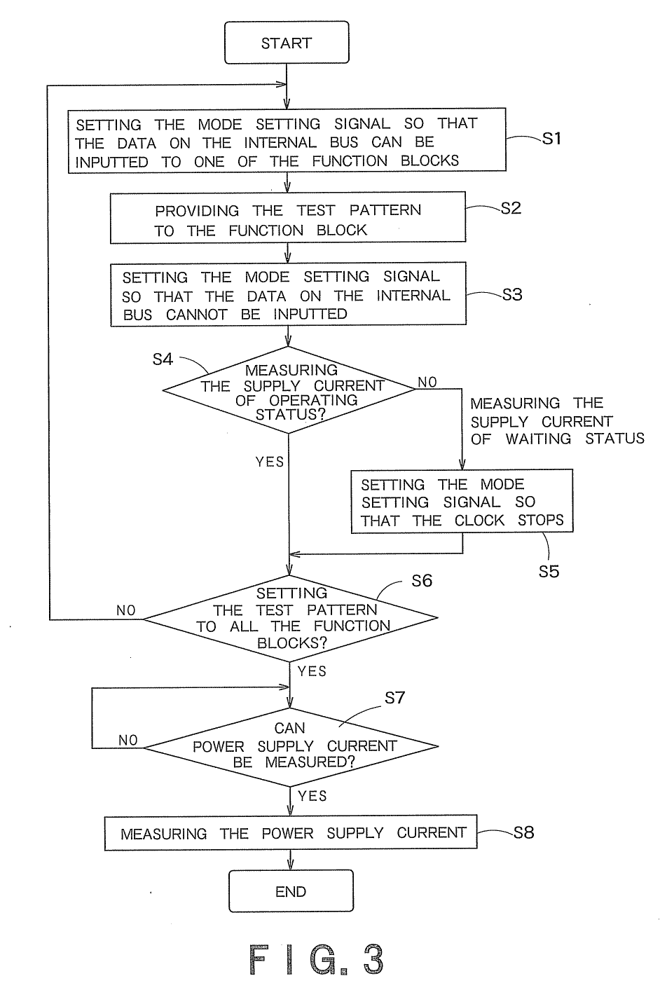

FIG. 3 is a flowchart showing a processing operation of the power supply current measuring device 101 and the LSI tester 8 according to the present embodiment. The way for measuring the power supply current will be explained with reference to FIG. 3.

Firstly, the LSI tester 8 selects one of the function blocks 1a to 1d (here, selects function block 1a). Then the LSI tester 8 sets the mode setting signal so that the selected function block 1a can be provided with the test patterns. The test control register 1a in the interface circuit 2a sets the input control signal so that the input control circuit 13a can provide the data input terminal IN[n:0] with the data on the internal bus 3 (Step S1). Note that the test control registers in the interface circuits 2b to 2d set the input control signal so that the data on the internal bus 3 cannot be provided to the function block 1b to 1d at this time.

Secondly, the LSI tester 8 provides the test patterns for measuring the power supply current flowing through the selected function block 1a from the input/output terminal 4 (Step S2). The test patterns are inputted to the data input terminal IN[n:0] of the function block 1a through the input control circuit 13a. Then the provided, test patterns are held by the data hold circuit 14a. Therefore, the test patterns once inputted by the LSI tester 8 keeps being provided to the function block 1a. Because of this, the function block 1a is set to be in a status where the power supply current can be measured.

At this time, the function blocks 1b to 1d are not provided with the test patterns for the function block 1a. This is because the input control signals in the interface circuits 2b to 2d are not set so that the function blocks 1b to 1d can be provided with the data on the internal bus 3, as described above.

After that, the LSI tester 8 sets the mode setting signal so that the function block 1a is not provided with the data on the internal bus 3 (Step S3). After processing of Step S3, the data hold circuit 14a keeps holding the test patterns for the function block 1a. Therefore, the function block 1a can hold the status where the power supply current can be measured.

Furthermore, when the power supply current is measured at a status where the function block 1a does not perform operation, that is, a waiting status (Step S4), the LSI tester 8 sets the mode setting signal so that the function block 1a is not provided with the internal clock. Then the test control register 11a in the function block 1a sets the clock control signal so that the clock stop circuit 12a stops providing the internal clock to the clock input terminal CLKin (Step S5).

The above processings of Step S1 to S5 are performed even in the other function blocks 1b to 1d (Step S6).

Because the test patterns for measuring the power supply current differ depending on the function blocks 1a to 1d, the test patterns cannot be provided to a plurality of function blocks at the same time. However, in the present embodiment, one of the function blocks 1a to 1d is selected in accordance with the mode setting signal, and the test patterns depending on the selected function block can be provided. Furthermore, once the test patterns are provided, the test patterns are held by the data hold circuit 14a. Therefore, all the function blocks 1a to 1d can be provided with the test patterns from the single input/output terminal 4 without switching the connection between the LSI tester 8 and the semiconductor device 100, thereby shortening the time required for measuring the power supply current.

Then the LSI tester 8 waits until the function blocks 1a to 1d become a status where the power supply current can be measured (Step S7). This is because some function blocks need time to become the status where the power supply current can be measured. More specifically, the LSI tester 8 obtains the output data from the output terminal OUT[n:0] of the function blocks 1a to 1d by turns by switching the mode setting signal. The output data includes information indicative of the status of each of the function blocks 1a to 1d. The LSI tester 8 waits until the LSI tester 8 determines that all the function blocks 1a to 1d are in the status where the power supply current can be measured based on the output data.

Note that the waiting of Step S7 is unnecessary when the function blocks 1a to 1d become the status where the power supply current can be measured right after providing the test patterns. Otherwise, Step S7 may be omitted and the LSI tester 8 may be waited until the function blocks 1a to 1d surely become the status where the power supply current can be measured. This is also effective when some of the function blocks 1a to 1d do not output the signal indicative of whether or not the power supply current can be measured.

After all the function blocks 1a to 1d becomes the status where the power supply current can be measured, the ampere meters 6a to 6d simultaneously measure the power supply current of the function blocks 1a to 1d (Step S8). The reason of simultaneously measuring the current is to measure the power supply current in a short time. Based on the measurement result, it is possible to calculate the consumption power of each of the function blocks 1a to 1d and/or to determine whether the function block operates normally.

As described above, in the present embodiment, the interface circuits 2a to 2d are provided corresponding to each of the function blocks 1a to 1d, and the LSI tester 8 can provide all the function blocks 1a to 1d with the test patterns for measuring the power supply current through the common input/output terminal 4. Therefore, the test patterns depending on each of the function blocks 1a to 1d can be provided without switching the connection between the LSI tester 8 and the semiconductor device 100. Because of this, even if a plurality of function blocks 1a to 1d are supplied with the power supply voltages VDDa to VDDd separately from the power supply devices 7a to 7d, the power supply current can be measured in a short time. Furthermore, because each of the function blocks 1a to 1d is provided with the clock stop circuit 12a, not only the power supply current in the operating status, but also that in the waiting status can be measured. In addition, because the LSI tester 8 obtains the signal indicative of whether or not the function blocks 1a to 1d are in the status where the power supply current can be measured from the function blocks 1a to 1d, the power supply current can be measured after the function blocks 1a to 1d surely becomes the status where the power supply current can be measured, thereby improving accuracy of the measurement.

An example where each of the function blocks 1a to 1d is supplied with the power supply voltage by their own power supply devices 7a to 7d has been explained. However, when one power supply device can generate multiple different voltages, each of the multiple different voltages generated by the power supply device can be supplied to each of the function blocks 1a to 1d through separate power supply lines.

Although based on above description, those skilled in the art can figure out additional effects and variations of the present invention, the aspect of the present invention is not limited to the stated each embodiments. Various additions, alterations and partial deletions can be done to the present invention within the conceptualistic thought and purpose of the present invention drawn on the claims and the equivalents.

1. A semiconductor device comprising:
an input/output terminal configured to input test patterns;
a plurality of function blocks configured to be driven by power supply voltage supplied through separate power supply lines;
an internal bus configured to send and receive at least the test patterns between the function blocks and the input/output terminal; and
an input control circuit which is provided corresponding to each of the plurality of function blocks and switches whether to provide the test patterns on the internal bus to the corresponding function block based on a mode setting signal.

2. The device of claim 1 further comprising:
a data hold circuit which is provided corresponding to each of the plurality of function blocks and holds the test patterns after switched by the input control circuit and before being provided to the corresponding function block.

3. The device of claim 2, wherein the test patterns are used for measuring the power supply current flowing through the plurality of function blocks,
the test patterns held by the data hold circuit are continuously provided to the corresponding function blocks until measurement of the power supply current flowing through the plurality of function blocks is completed.

4. The device of claim 1, wherein the mode setting signal includes information indicative of whether to provide each of the plurality of function blocks with an internal clock for operating the corresponding function block;
further comprising a clock stop circuit which is provided corresponding to each of the plurality of function blocks and switches whether to provide the corresponding function block with the internal clock based on the mode setting signal.

5. The device of claim 4, wherein the plurality of function blocks flows a power supply current in an operating status when the clock stop circuit provides the internal clock and flows the power supply current in a waiting status when the clock stop circuit stops providing the internal clock.

6. The device of claim 1, wherein the mode setting signal includes information indicative of whether to provide the internal bus with an output signal of the corresponding function block;
further comprising an output control circuit which is provided corresponding to each of the plurality of function blocks and switches whether to provide the internal bus with the output signal of the corresponding function block based on the mode setting signal, the output signal including information indicative of whether a current measurement of the corresponding function block is possible.

7. The device of claim 1, wherein the mode setting signal includes:
information indicating that which of the function blocks is provided with which of the test patterns,
information indicative of whether to provide each of the function blocks with an internal clock for operating the corresponding function block, and
information indicative of whether to provide the internal bus with an output signal of the corresponding function block.

8. A power supply current measuring device comprising:
a large-scale integrated circuit (LSI) tester configured to provide test patterns and a mode setting signal;
an internal bus configured to send and receive at least the test patterns between a plurality of function blocks driven by power supply voltages supplied through separate power supply lines and the LSI tester;
an input control circuit which is provided corresponding to each of the plurality of function blocks and switches whether to provide the test patterns on the internal bus to the corresponding function block based on the mode setting signal; and
a plurality of ampere meters configured to simultaneously measure a power supply current of the plurality of function blocks.

9. The device of claim 8 further comprising:
a data hold circuit which is provided corresponding to each of the plurality of function blocks and holds the test patterns after switched by the input control circuit and before being provided to the corresponding function block.

10. The device of claim 9, wherein the test patterns are used for measuring the power supply current flowing through the plurality of function blocks,
the test patterns held by the data hold circuit are continuously provided to the corresponding function blocks until measurement of the power supply current flowing through the plurality of function blocks is completed.

11. The device of claim 8, wherein the mode setting signal includes information indicative of whether to provide each of the plurality of function blocks with an internal clock for operating the corresponding function block;
further comprising a clock stop circuit which is provided corresponding to each of the plurality of function blocks and switches whether to provide the corresponding function block with the internal clock based on the mode setting signal.

12. The device of claim 11, wherein each of the ampere meters measures the power supply current of the corresponding function block in an operating status when the clock stop circuit provides the internal, clock and measures the power supply current of the corresponding function block in a waiting status when the clock stop circuit stops providing the internal clock.

13. The device of claim 8, wherein the mode setting signal includes information indicative of whether to provide the internal bus with an output signal of the corresponding function block;
further comprising an output control circuit which is provided corresponding to each of the plurality of function blocks and switches whether to provide the internal bus with the output signal of the corresponding function block based on the mode setting signal, the output signal including information indicative of whether a current measurement of the corresponding function block being possible, and the LSI tester determining whether all the plurality of function blocks are in the status where measurement of the power supply current is possible based on the output signal.

14. The device of claim 13, wherein the LSI tester simultaneously measures the power supply current of the plurality of function block using the plurality of ampere meters after the LSI tester determines that all the function blocks are in the status where measurement of the power supply current is possible.

15. The device of claim 8, wherein the mode setting signal includes:
information indicating that which of the function blocks is provided with which of the test patterns, and
information indicative of whether to provide each of the function blocks with an internal clock for operating the corresponding function block, and
information indicative of whether to provide the internal bus with an output signal of the corresponding function block.

16. A power supply current measuring method comprising:
outputting a test pattern and a mode setting signal from a large-scale integrated circuit (LSI) tester;
providing a plurality of function blocks driven by power supply voltages supplied through separate power supply line with the test pattern through an internal bus between the plurality of function blocks and the LSI tester;
switching whether to provide the test pattern on the internal bus to the corresponding function block based on the mode setting signal by an input control circuit corresponding to each of the plurality of function blocks; and
measuring a power supply current of the plurality of function blocks by a plurality of ampere meters simultaneously.

17. The method of claim 16, wherein a data hold circuit which is provided corresponding to each of the plurality of function blocks holds the test patterns after switched by the input control circuit and before being provided to the corresponding function block.

18. The method of claim 17, wherein the test patterns are for measuring the power supply current flowing through the plurality of function blocks,
the test patterns held by the data hold circuit are continuously provided to the corresponding function blocks until measurement of the power supply current flowing through the plurality of function blocks is completed.

19. The method of claim 16, wherein the mode setting signal includes information indicative of whether to provide each of the plurality of function blocks with an internal clock for operating the corresponding function block; and
a clock stop circuit which is provided corresponding to each of the plurality of function blocks switches whether to provide the corresponding function block with the internal clock based on the mode setting signal.

20. The method of claim 16, wherein the mode setting signal includes information indicative of whether to provide the internal bus with an output signal of the corresponding function block,
an output control circuit which is provided corresponding to each of the plurality of function blocks switches whether to provide the internal bus with the output signal of the corresponding function block based on the mode setting signal, the output signal including information indicative of whether a current measurement of the corresponding function block being possible, and the LSI tester determining whether all the plurality of function blocks are in the status where measurement of the power supply current is possible based on the output signal.
